(19) United States
(12) Patent Application Publication
(10) Pub. No.: US 2021/0083601 A1
(43) Pub. Date: Mar. 18, 2021

(54) DEVICE FOR CONVERTING MECHANICAL ENERGY INTO ELECTRICAL ENERGY OPERATING OVER AN EXTENDED RANGE OF VIBRATION FREQUENCIES

(71) Applicants: COMMISSARIAT A L'ENERGIE ATOMIQUE ET AUX ENERGIES ALTERNATIVES, Paris (FR); UNIVERSITE SAVOIE MONT BLANC, Chambery (FR)

(72) Inventors: David GIBUS, Grenoble Cedex 09 (FR); Adrien BADEL, Lescheraines (FR); Olivier FREYCHET, Grenoble Cedex 09 (FR); Pierre GASNIER, Grenoble Cedex 09 (FR)

(73) Assignees: COMMISSARIAT A L'ENERGIE ATOMIQUE ET AUX ENERGIES ALTERNATIVES, Paris (FR); UNIVERSITE SAVOIE MONT BLANC, Chambery (FR)

(21) Appl. No.: 17/022,785

(22) Filed: Sep. 16, 2020

(30) Foreign Application Priority Data
Sep. 17, 2019 (FR) 19 10240

(51) Int. Cl. H02N 2/18; H01L 41/04; H01L 41/113

(52) U.S. Cl. CPC H02N 2/188; H02N 2/181; H01L 41/1136; H01L 41/042

(57) ABSTRACT

A device for converting mechanical energy into electrical energy including a support (2), a structure (S1) suspended to the support through embedding by a first longitudinal end (4.1) and including a mass (M) fastened to a second longitudinal end (4.2), two layers of piezoelectric material (12, 14) extending between the first longitudinal end (4.1) and second longitudinal end (4.2) of the structure (S1) and disposed so that, when the mass (M) moves, the layers are flexurally deformed, electrodes (E1, E2) on either side of the layer of piezoelectric material (12, 14), wherein the structure (S1) includes transverse elements (16, 18) integral with the layers of piezoelectric material (12, 14) extending transversely relative to the longitudinal direction (X) of the structure over a length at least equal to half the transverse dimension (L) of the layers of piezoelectric material (12, 14).

### TECHNICAL FIELD AND STATE OF PRIOR ART

The present invention relates to a device for converting mechanical vibrations into electrical energy operating over an extended range of vibration frequencies.

It is more and more attempted to recover lost mechanical energy, especially vibrations, to produce electricity. For example, they can be vibrations of an airplane or car engine when it operates or vibrations generated during a movement.

For this, it is known to use devices including a piezoelectric material which, when it is deformed for example under the effect of vibrations, generates electricity.

Such a device can include a vibrating structure comprising a beam embedded at a longitudinal end into a support and a mass fastened to the other longitudinal end, two layers of piezoelectric material on both faces of the beam and electrodes to collect electric charges generated. When the environment undergoes vibrations, the mass oscillates and the layers of piezoelectric material are deformed, generating electric charges which are collected.

Such a vibrating structure has a resonant frequency defined by its mechanical characteristics. This structure has the drawback of being frequency-selective, i.e. it ensures conversion of mechanical vibrations at frequencies close to the resonant frequency of the structure. It is therefore not adapted to an application to systems vibrating over an extended frequency range.

### DISCLOSURE OF THE INVENTION

One purpose of the present invention is therefore to offer a device for converting mechanical energy into electrical energy the operation of which over a wide frequency range is improved.

The purpose set forth above is achieved by a device for converting mechanical vibrations into electricity including a support, a suspended structure including at least one beam embedded into the support by an end, and a mass fastened to the other end of the beam, a piezoelectric material on at least one of the faces of the beam so as to undergo a flexure upon deforming the beam, and at least one transverse element extending substantially transversely relative to the direction of the beam over at least half the width of the piezoelectric material.

The at least one transverse element therefore limits the transverse deformation of the structure while enabling a flexural deformation of the structure, electromechanical coupling of the structure is then increased, which raises the capacity to adapt the resonant frequency of the structure to adapt to modifications of the vibration frequency of the environment. Thus, a frequency adjustable device is made, enabling the frequency range of recoverable vibrations to be extended.

By virtue of the invention, by means of a control circuit, it is possible to control the resonant frequency of the structure so that it is close to the vibration frequency of the support, which enables energy recovery to be optimised.

Preferably, the at least one transverse element is rigid and has a reduced dimension in the longitudinal direction of the structure, in order to limit at best transverse deformation of the structure while reducing impact on flexural deformation of the structure.

For example, the device includes transverse elements on either side of the neutral axis of the beam.

Advantageously, the transverse elements are distributed along the structure.

The transverse elements preferably have a high rigidity. Moreover, they preferably have a low dimension in the length direction of the structure to limit their effect on longitudinal deformation.

One subject-matter of the present application is thereby a device for converting mechanical energy into electrical energy including a support, a structure extending along a longitudinal direction, said structure being suspended to the support through embedding by a first longitudinal end and including a mass fastened to a second longitudinal end, at least one layer of piezoelectric material at least partly extending between the first longitudinal end and second longitudinal end of the structure and disposed so that, when the mass moves in a direction orthogonal to the longitudinal direction, the layer is flexurally deformed, electrodes on either side of the layer of piezoelectric material. The structure includes at least one transverse element integral with the layer of piezoelectric material extending transversely relative to the longitudinal direction over a length at least equal to half the transverse dimension of the layer of piezoelectric material.

Embedding the structure into the support, i.e. the embedding connection between the structure and the support, can be achieved by manufacturing as a single piece the support and the structure or by intermediate means connecting the structure to the support through embedding.

### BRIEF DESCRIPTION OF THE DRAWINGS

The present invention will be better understood based on the following description and accompanying drawings in which:

FIG. 1A is a schematically represented perspective view of an example of an energy recovery device.

FIG. 1B is a schematic longitudinal cross-section view of the device of FIG. 1A.

FIG. 1C is a perspective view of an example of a transverse element represented alone.

FIGS. 2A and 2B are top views of an example of recovery device according to the invention representing amplitudes of longitudinal and transverse deformation in grey levels.

FIGS. 3A and 3B are top views of a recovery device of the state of the art representing amplitudes of longitudinal and transverse deformation in grey levels.

FIG. 4 is a longitudinal cross-section view of an alternative embodiment of an energy recovery device.

FIG. 5 is a longitudinal cross-section view of another alternative embodiment of an energy recovery device.

FIG. 6 is a longitudinal cross-section view of another example of embodiment of an energy recovery device.

FIG. 7 is a longitudinal cross-section view of another example of embodiment of an energy recovery device.

FIGS. 8 to 10 represent variants of an energy recovery device of FIG. 6.

### DETAILED DISCLOSURE OF PARTICULAR EMBODIMENTS

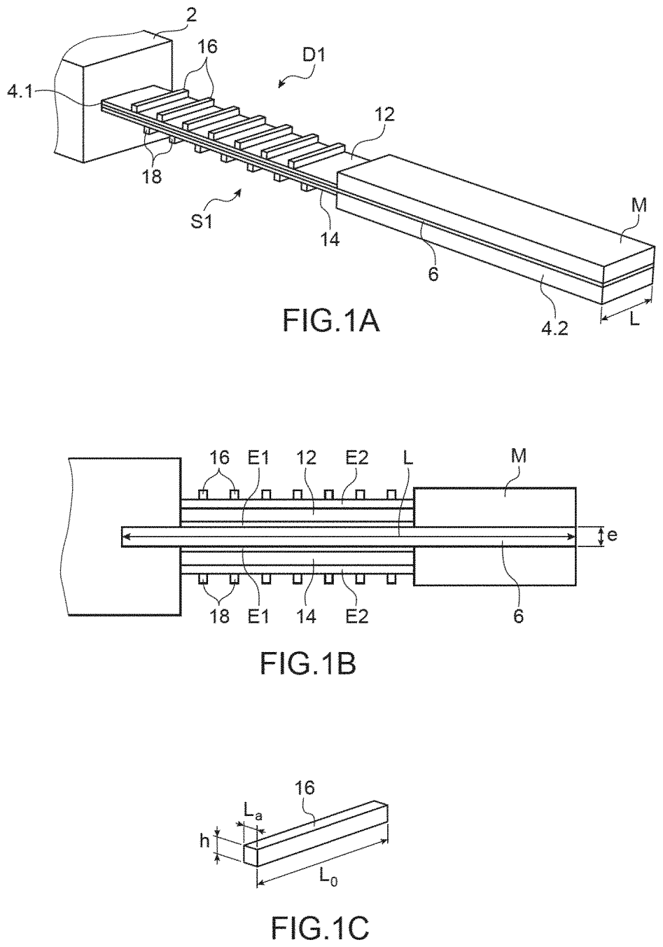

In FIGS. 1A and 1B, an example of an energy recovery device D1 can be seen, including a support 2 for being fastened to a system experiencing vibrations, such as a chassis of an automotive vehicle, a structure S1 embedded into the support 2.

The structure S1 extends along the longitudinal direction X. It includes a longitudinal end 4.1 embedded into the support and a mass M fastened to its other longitudinal end 4.2. The structure S1 is to vibrate along the direction Z orthogonal to the direction X. In this example, the mass M extends on either side of the neutral axis of the structure. As a variant, it extends above or under the same.

The structure includes a beam 6 which is embedded into the support and which carries the mass M. The beam has a low thickness e, width L and length l. Preferably, l/e>5.

The beam 6 then includes two opposite faces 8, 10 orthogonal to the direction Z.

The structure also includes layers of piezoelectric material 12, 14 fastened to both opposite faces 8, 10 of the beam 6.

Electrodes E1, E2, represented in FIG. 1B, on either side of the piezoelectric layer 12, 14 are provided to collect charges generated upon the layers and/or to apply bias. The electrodes are connected to an electric circuit C.

Preferably, the transverse elements are located as close as possible to the piezoelectric layers, advantageously in contact with the same, or directly in contact with the electrodes. In FIGS. 1A and 1B, the transverse elements 16 are associated with the layer 12 and mainly have an action on the same, and the transverse elements 18 are associated with the layer 14 and mainly have an action on the same.

For example, the beam can be made of a metal material or alloy, such as steel, brass, aluminium, silicon, of a polymeric material such as epoxy.

The mass can be made of a metal material or alloy, such as steel, brass, aluminium, tungsten or silicon,

The piezoelectric layer is for example made of PZT (Lead zirconate titanium), PMN-PT (Lead-Magnesium-Niobate-Lead-Titanium), PZN-PT (Lead-Zinc-Niobate-Lead-Titanium), AlN, PVDF (polyvinylidene fluoride).

The electrodes are for example of silver, gold or copper.

In the example represented, the mass is directly fastened to the beam and the piezoelectric layers only cover the free zones of the faces 8 and 10.

Preferably, the layers 12 and 14 entirely cover the free zones of the faces 8 and 10, maximising the amount of piezoelectric material and therefore the amount of electric charges which can be generated. A device in which the piezoelectric layer(s) does/do not entirely cover the free zone(s) of the face(s) of the beam does not depart from the scope of the present invention.

Thus, when vibrations are applied to the support, the suspended mass moves along the direction Z orthogonal to the direction X, flexurally deforming the beam and the layers 12, 14 generating electric charges.

In the example represented, the structure includes transverse elements 16 fastened to the electrodes located on the outermost side of the stack. Dimensions and/or rigidity of the transverse elements are selected to limit transverse deformation of the structure, especially of the piezoelectric material.

The transverse elements 16, 18 extend over at least half the width of the layers 12, 14. In the example represented and preferably, without being limited thereto, the layers 12, 14 have the same width as the beam. A structure in which the piezoelectric layer(s) are wider or less wide than the beam does not depart from the scope of the present invention.

Preferably, the transverse elements have a length equal to the width of the layers 12, 14.

The transverse elements 12, 14 are preferably parallel to each other and orthogonal to the direction X reducing their effect on flexural deformation of the structure.

The material of the transverse elements is a material having some rigidity. By way of example, the transverse elements are made of cobalt or manganese for the use of deposition techniques. Steel or brass enables several millimetre long bars to be made in a simplified manner.

The transverse elements have a dimension in the direction Z, referred to as the height h (FIG. 1C), sufficient to offer some rigidity. Preferably, the transverse elements all have the same height, enabling manufacture to be simplified.

The width La (FIG. 1C) is selected to offer some rigidity to the transverse element without the latter hindering flexural deformation of the structure.

Preferably, materials of the beam and transverse elements are selected so that:

$$\frac{{E}_{bar}}{{E}_{piezo}} \frac{{L}_{tot}}{{L}_{p}} < 20 ¶$$

$$\frac{Ebar}{Epiezo} = \frac{number of transverse elements \times length of a transverse element}{Lp} < 20$$

with E bar: Young's modulus of the transverse elements,

E piezo: Young's modulus of the piezoelectric layer,

Lp: beam length,

Ltot: sum of the lengths of the transverse elements.

Moreover, heights of the transverse elements and thickness of the piezoelectric layer can be advantageously selected so that:

$$\frac{{E}_{bar}}{{E}_{piezo}} * {( \frac{{h}_{bar}}{{h}_{piezo}} )}^{3} > {10}^{- 3}$$

with hbar=thickness of the transverse elements hpiezo: thickness of the piezoelectric layer.

The thickness of the beam can also be advantageously selected so that:

$$\frac{Ebar}{Emoy} \times {( \frac{hbar}{beam thickness} )}^{3} > {27.10}^{- 3}$$

with

Emoy=(thickness of the piezoelectric layer×Epiezo+beam thickness×Ebeam)/Eptotale

Ebeam being the Young's modulus of the beam,

Eptotale being the total thickness of the beam which is equal to the sum: thickness of the piezoelectric layer+thickness of the beam.

The ratio h/La is at least equal to 10⁻², preferably at least equal to 2·10⁻¹ and more preferably greater than 1.

The transverse element has a length Lo.

Furthermore, the number of transverse elements and their distribution along the direction X also enable their effect in limiting the transverse deformation of the structure to be adjusted.

In the example represented, the transverse elements 16, 18 on the layers 12, 14 on either side of the beam are distributed in staggered rows. This distribution is particularly advantageous when the number of transverse elements is reduced. Indeed, the transverse elements 16 thus distributed can have an effect on the layer 14 even if the same is reduced relative to the effect they have on the layer 12. Limiting the transverse deformation is then distributed at best along the length of the beam.

In this example, the transverse elements are evenly distributed over the whole length of the layers 12, 14.

Preferably, the distance between two parallel faces facing two adjacent transverse elements is greater than La, the width of the transverse elements.

The transverse elements can have dimensions different from each other, for example depending on their disposition relative to the embedding zone.

Implementing layers of piezoelectric material on either side of the neutral axis of the beam enables energy recovery to be optimised. It will be understood that a structure including a single layer of piezoelectric material does not depart from the scope of the present invention.

The vibrating structure has a resonant frequency Fr1, which is set by dimensions of the different elements of the structure, their dimensions and mechanical properties. It is the frequency at which the structure has the most recovered energy.

Preferably, the device includes a circuit for controlling CC the resonant frequency of the structure enabling the mechanical resonant frequency of the structure to be adjusted.

For example, the control circuit includes an adjustable impedance electric charge. Depending on the desired mechanical resonant frequency, the control circuit CC matches the impedance connected across the electrodes. Indeed, by modifying the electric conditions of the piezoelectric material, the latter stiffens or softens; which modifies the resonant frequency of the structure. Advantageously, the control circuit sets the mechanical resonant frequency of the structure such that it is close or equal to the vibration frequency of the system.

Preferably, the mechanical resonant frequency is selected so that:

|Resonant frequency−Vibration Frequency|/(Vibration Frequency)<5%.

For example, an automated frequency tracking system can be implemented to manage the mechanical resonant frequency. This capacity to adjust the resonant frequency is all the greater that the electromechanical coupling coefficient is great. Thus, by virtue of the invention, the device can be adapted to environments vibrating at various frequencies while keeping a high recovered power.

By way of illustration of the effect of the invention, longitudinal and transverse deformations of different structures and coupling gain have been estimated by finite element simulations, for example using the COMSOL® software.

The structure considered is that of FIG. 1A. The structures considered are the following ones: unlike the structure of FIG. 1A, it includes a piezoelectric layer 12 with transverse elements fastened to this layer:

The layers 12 and 14 are of a piezoelectric material: [001]-oriented PMN-PT. Since the electrodes are very thin, for example of a thickness of at least 10 times lower than the thickness of the piezoelectric material, their effect is insignificant.

The piezoelectric layers 12, 14 have a length of 45 mm, a width of 10 mm and a thickness of 0.5 mm.

The steel mass has a length of 45 mm, a width of 10 mm and a thickness of 5 mm.

The steel beam has a length of 45 mm, a width of 10 mm and a thickness of 0.5 mm.

14 steel transverse elements having length l=10 mm, height h=1 mm and width L=1 mm, distributed on either side of the neutral axis of the beam.

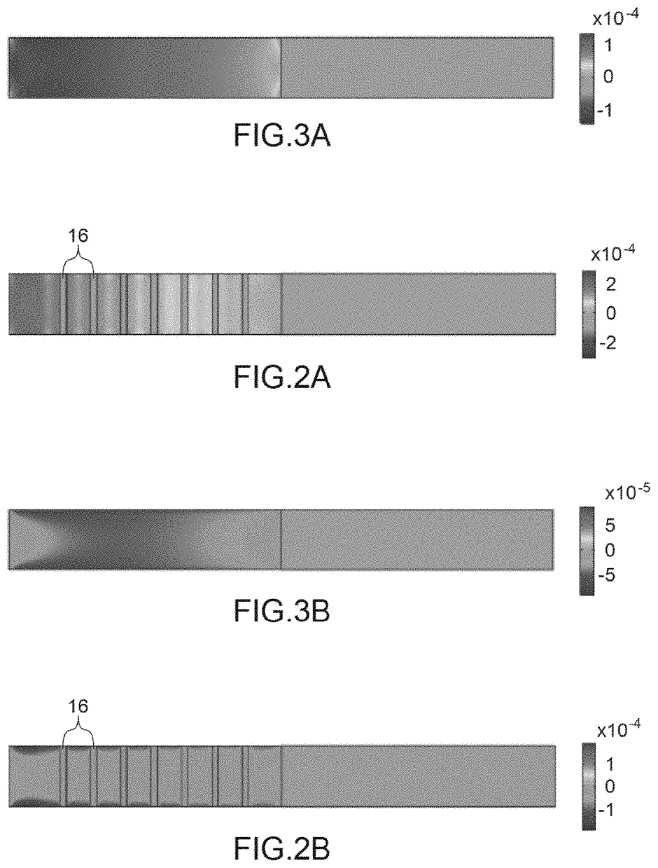

In FIGS. 2A and 2B, the longitudinal deformation and transverse deformation, respectively, of a structure according to the invention, i.e. can be seen represented i.e. fitted with transverse elements. The deformation amplitude is represented in grey levels. It is noticed that the structure has little transverse deformation. The electromechanical coupling coefficient for this structure is equal to 37.71%. The scale in FIG. 2A corresponds to the ratio Δl/I and the scale in FIG. 2B corresponds to the ratio ΔL/L.

By way of comparison, in FIGS. 3A and 3B, the longitudinal deformation and transverse deformation, respectively, of a structure of the state of the art can be seen represented i.e. without a transverse element and having the above dimensions. The electromechanical coupling coefficient of the structure of the state of the art is equal to 21.34%. The deformation amplitude is represented in grey levels. The scale in FIG. 3A corresponds to the ratio Δl/I and the scale in FIG. 3B corresponds to the ratio ΔL/L.

It is noticed that the structure according to the invention has a substantially reduced transverse deformation relative to that of the structure of the state of the art while having a substantially identical longitudinal deformation. Furthermore, the electromechanical coupling coefficient is multiplied by 1.75 by virtue of the invention, whereas the closed loop resonant frequency is not much modified.

In the example represented, several transverse elements are implemented. However, a structure with one transverse element on each layer 12, 14 has an electromechanical coupling coefficient multiplied by 1.25 relative to that of a structure of the state of the art.

For example, the transverse elements are joined to the structure. For example, they are adhered to the structure.

Alternatively, the transverse elements are made according to techniques of microelectronics, i.e. by layer deposition and structuring, for example by etching.

The operation of the recovery device D1 will be described.

When the system to which the support of the device is fastened undergoes vibrations, the suspended mass M moves along the direction Z, flexurally deforming the beam and piezoelectric layers which is vibrated. This deformation causes electric charges which are collected and transmitted to the electric circuit C to be generated. If vibrations undergone by the system are close to the resonant frequency Fr1 of the structure, recovery is optimum. Generating electric charges is all the greater that the longitudinal deformation of the structure is great.

Preferably, the control circuit CC adjusts the mechanical resonant frequency of the structure beforehand so that it is close to the frequency(ies) of vibrations to be recovered.

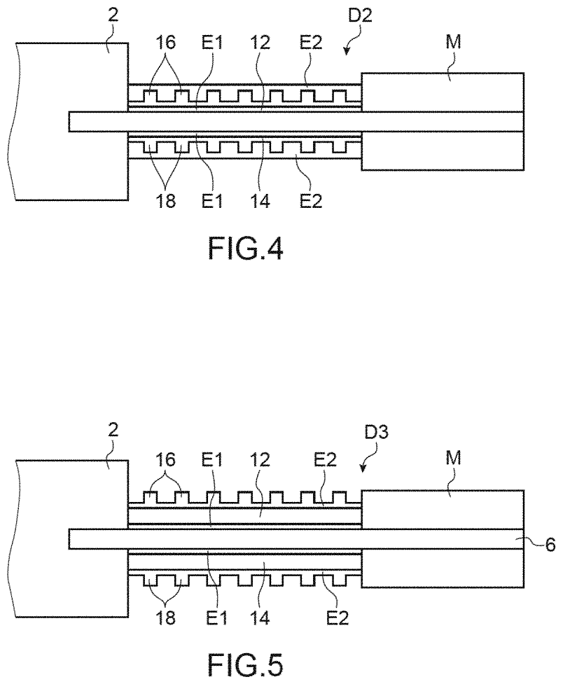

In FIG. 4, an alternative embodiment D2 can be seen, in which the transverse elements 16, 18 are of a piezoelectric material and made as a single piece with the layers 12, 14.

In FIG. 5, another alternative of embodiment D3 can be seen, in which it is the electrodes E2 which are structured to integrate the transverse elements 16, 18.

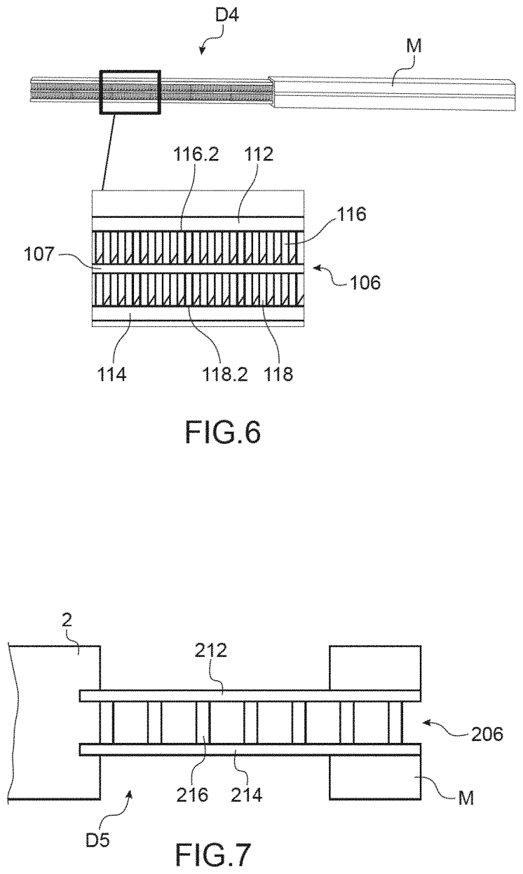

In FIG. 6, another example of embodiment D4 can be seen, in which it is the beam which carries the transverse elements. The beam 106 includes a central plate 107 and transverse elements 116, 118 on its two opposite faces, fastened to the plate 107 by a side edge 116.1, 118.1, advantageously disposed in staggered rows. The piezoelectric layers 112, 114 and their electrodes are fastened to the other side edge 116.2, 118.2 of each transverse element.

For example, the transverse elements are made by structuring a substrate by techniques of microelectronics. The piezoelectric layers and electrodes are made by deposition.

Alternatively, the transverse elements are joined one by one to the central plate 107, which makes it possible to use a more rigid material to manufacture the transverse elements relative to the material of the central plate which is to be flexurally deformed.

In FIG. 7, another example D5 can be seen, in which the beam 206 is only formed by transverse elements 216, the layers of piezoelectric material 212, 214 being fastened to the edges of the transverse elements 216.

According to one alternative of FIG. 7, transverse elements are also joined to the external face of the piezoelectric layers 212, 214.

In the above-described examples, the transverse elements have a rectangular or square cross-section. Other shapes are also contemplatable. They can have a trapezoidal cross-section, for example oriented so that the small base is on the side of the beam.

The beam 6 can have any shape mainly extending in the longitudinal direction, for example a corrugated or zigzag shape.

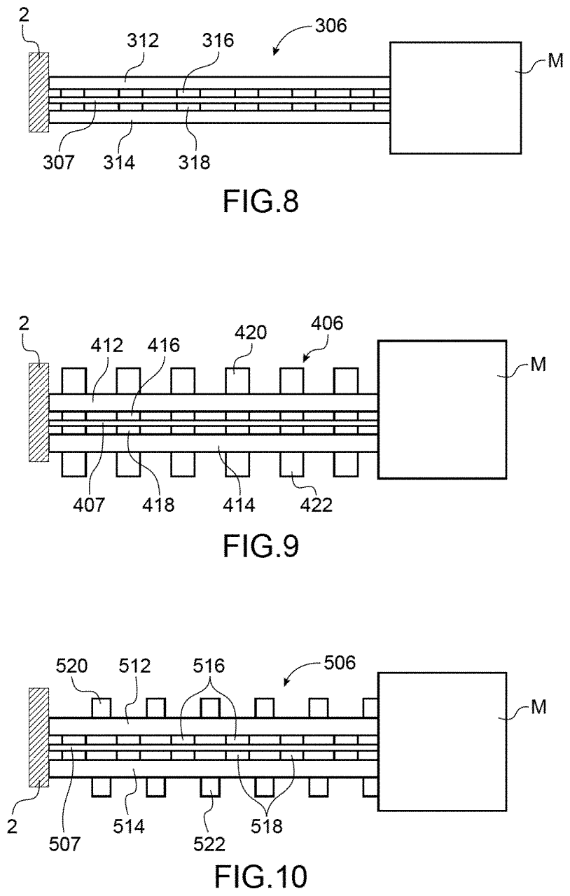

FIGS. 8 to 10 show variants of the device of FIG. 6.

In FIG. 8, the beam 306 comprises a central plate 307 and transverse elements 316, 318 on its two opposite faces which are fixed to the plate 307 by a lateral edge. The piezoelectric layers 312, 314 and their electrodes are fixed to the other lateral edge of each transverse element. In this variant, each transverse element 316 is aligned with a transverse element 318 in a direction orthogonal to the longitudinal direction of the beam.

In FIG. 9, the beam 406 comprises a central plate 407 and transverse elements 416, 418 on its two opposite faces which are fixed to the plate 407 by a lateral edge. The piezoelectric layers 412, 414 and their electrodes are fixed to the other lateral edge of each transverse element. The beam 406 comprises transverse elements 420 fixed on the outer face of the piezoelectric layer 412, situated on the opposite to the piezoelectric face in contact with the transverse elements 416. The beam 406 also comprises transverse elements 422 fixed to the outer face of the piezoelectric layer 414. In this variant, each transverse element 416 is aligned with a transverse element 418, a transverse element 420, a transverse element 422 in a direction orthogonal to the longitudinal direction of the beam.

In FIG. 10, the beam 506 comprises a central plate 507 and transverse elements 516, 518 on its two opposite faces which are fixed to the plate 507 by a lateral edge. The piezoelectric layers 512, 514 and their electrodes are fixed to the other lateral edge of each transverse element. The beam 506 comprises transverse elements 520 fixed on the outer face of the piezoelectric layer 512. The beam 406 also comprises transverse elements 522 fixed to the outer face of the piezoelectric layer 514. In this variant, each transverse element 516 is aligned with a transverse element 518, in a direction orthogonal to the longitudinal direction of the beam, and each transverse element 520 is aligned with a transverse element 522 in a direction orthogonal to the longitudinal direction of the beam. The transverse elements 516, 518 are distributed in staggered rows with respect to the transverse elements 520, 522.

In a non-shown variant, elements 516, 518, 520, 522 are distributed in staggered rows with respect to each other.

The number of piezoelectric layers can be higher than 2 and the number of transverse elements sets ca be higher than 4.

The device includes at least n layer of piezoelectric material(s), n being at least equal to 1 and at least one transverse element integral with at least one of the layers. Indeed a device with three layers of piezoelectric material and transverse elements associated with one layer falls within the scope of the present invention.

By virtue of the invention, a device which can be controlled to enable an optimised energy recovery over a wide frequency range is made.

The device is relatively easily made, especially by microelectronic methods.

A system including several recovery devices comprising structures with different resonant frequencies can be contemplated, which enables a still wider frequency range to be covered.

1. A device for converting mechanical energy into electrical energy including a support, a structure extending along a longitudinal direction, said structure being suspended to the support through embedding by a first longitudinal end,
Said structure including:
a mass fastened to a second longitudinal end,
at least one layer of piezoelectric material at least partly extending between the first longitudinal end and the second longitudinal end of the structure and disposed so that, when the mass moves in a direction orthogonal to the longitudinal direction, the layer is flexurally deformed, electrodes on either side of the layer of piezoelectric material,
transverse elements integral with the layer of piezoelectric material extending transversely relative to the longitudinal direction over a length at least equal to half the transverse dimension of the layer of piezoelectric material,
a beam including a central plate a longitudinal end of which is embedded into the support, and another longitudinal end of which carries the mass, said the transverse elements being fastened to at least one face of the central plate, the at least one layer of piezoelectric material being fastened to the edges of the transverse elements.

2. The device according to claim 1, wherein the transverse elements extend over the whole transverse dimension of the layer of piezoelectric material.

3. The device according to claim 1, including a plurality of transverse elements parallel to each other and distributed in the longitudinal direction.

4. The device according to one 3, wherein the transverse elements have a height h in the direction normal to the longitudinal direction and wherein all the transverse elements have the same height.

5. The device according to claim 1, wherein the transverse elements have a height h in the direction normal to the longitudinal direction and a width La in the longitudinal direction, the ratio h/La being greater than 10⁻², and preferably greater than 1.

6. The device according to claim 5, wherein the structure includes a second layer of piezoelectric material opposite to the first layer of piezoelectric material relative to the neutral axis of the structure.

7. The device according to claim 6, including transverse elements on the first and second layers of piezoelectric material disposed in staggered rows relative to each other.

8. The device according to claim 1, wherein the transverse elements are adhered.

9. The device according to claim 1, wherein the transverse elements are disposed along the neutral axis of the structure and layer of piezoelectric material(s) and/or are fastened to the edges of transverse elements.

10. The device according to claim 1, including an electric circuit connected to the electrodes and configured to collect electric charges produced by the layer of piezoelectric material(s).

11. The device according to claim 10, wherein the electric circuit includes a control circuit configured to apply an optimum electric charge across the at least one layer of piezoelectric material so as to set the resonant frequency of the structure to a given value.
